(19) United States
(12) Patent Application Publication
(10) Pub. No.: US 2009/0109642 A1
(43) Pub. Date: Apr. 30, 2009

(54) SEMICONDUCTOR MODULES AND ELECTRONIC DEVICES USING THE SAME

(75) Inventors: Hyun-Soo Chung, Hwaseong-si (KR); Dong-Ho Lee, Seongnam-si (KR); Seong-Deok Hwang, Seoul (KR); Sun-Won Kang, Seongman-si (KR); Ki-Hyuk Kim, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/249,047

(22) Filed: Oct. 10, 2008

(30) Foreign Application Priority Data
Oct. 26, 2007 (KR) 2007-108414

(51) Int. Cl. H05K 7/00

(52) U.S. Cl. 361/783

(57) ABSTRACT

Semiconductor devices and electronic devices using the same. The semiconductor module may include a first semiconductor chip, and a module substrate having a top surface on which the first semiconductor chip is mounted and a second surface opposite the top surface, wherein the module substrate includes a first buffer layer to relieve stress occurring due to a difference of thermal expansions between the first semiconductor chip and the module substrate.

### CROSS-REFERENCE TO RELATED APPLICATIONS

This U.S. non-provisional patent application claims priority under 35 U.S.C. §119 to Korean Patent Application No. 10-2007-0108414 filed on Oct. 26, 2007, the entire contents of which are incorporated herein by reference.

### BACKGROUND OF THE INVENTION

1. Field of the Invention

The present general inventive concept relates to semiconductor modules and electronic devices using the same. More particularly, the present general inventive concept relates to semiconductor modules with improved reliability and electronic devices using the same.

2. Description of the Related Art

Demands for the densification, high speed and size minimization of memory and semiconductor modules become influential to advance the performance of computer systems. Wafer level packaging techniques are suggested to meet these demands. Solder joint cracks may occur in wafer level package modules in which a wafer level package is mounted on a module substrate by solder balls due to different thermal expansions between the wafer level package and the module substrate. Solder joint cracks may deteriorate the reliability of the wafer level package module. Therefore, it is required to improve module substrates and wafer level package modules to prevent the solder joint cracks.

### SUMMARY OF THE INVENTION

Exemplary embodiments of the present inventive concept are directed to semiconductor modules with improved reliability and electronic devices using the same.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept can be achieved by providing a semiconductor module that may include a first semiconductor chip; and a module substrate having a top surface on which the first semiconductor chip is mounted and a second surface opposite the top surface, wherein the module substrate include a first buffer layer to relieve stress occurring due to difference of thermal expansions between the first semiconductor chip and the module substrate.

In some embodiments herein, the first buffer layer may be located inside the module substrate, and a size and area thereof may be identical to those of the first semiconductor chip.

In some embodiments herein, the module substrate may further include a core having a third surface and a fourth surface opposite the third surface; a first conductive layer disposed on the third surface and electrically connected to the first semiconductor chip; and a first insulative layer exposing a portion of the first conductive layer, wherein the first buffer layer is interposed between the third surface and the first conductive layer.

In some embodiments herein, the first buffer layer may be located inside the module substrate and may include a frame structure in the form of a band extending along the first semiconductor chip.

In some embodiments herein, the module substrate may further include a core having a third surface and a fourth surface opposite the third surface; a first conductive layer disposed on the third surface and electrically connected to the first semiconductor chip; and a first insulative layer exposing a portion of the first conductive layer, wherein the first buffer layer lies on the third surface to contact a lateral side of the first conductive layer.

In some embodiments herein, the first buffer layer may include one of a polymer and an elastomer each having a Young's modulus of 2 GPa or less.

In some embodiments herein, the module substrate may further include a second semiconductor chip mounted on the second surface; and a second buffer layer to relieve stress occurring due to difference of thermal expansions between the second semiconductor chip and the module substrate.

In some embodiments herein, the module substrate may further include a core having a third surface and a fourth surface opposite the third surface; a first conductive layer disposed on the third surface and electrically connected to the first semiconductor chip; a first insulative layer exposing a portion of the first conductive layer; a second conductive layer disposed on the fourth surface and electrically connected to the second semiconductor chip; and a second insulative layer exposing a portion of the second conductive layer, wherein the first buffer layer is interposed between the third surface and the first conductive layer, and the second buffer layer is interposed between the fourth surface and the second conductive layer.

In some embodiments herein, the second buffer layer may be located inside the module substrate and may comprise a frame structure in the form of band extending along the second semiconductor chip.

In some embodiments herein, the module substrate may further include a core having a third surface and a fourth surface opposite the third surface; a first conductive layer disposed on the third surface and electrically connected to the first semiconductor chip; a first insulative layer exposing a portion of the first conductive layer; a second conductive layer disposed on the fourth surface and electrically connected to the second semiconductor chip; and a second insulative layer exposing a portion of the second conductive layer, wherein the first buffer layer lies on the third surface to contact a lateral side of the first conductive layer, and the second buffer layer lies on the fourth surface to contact a later side of the second conductive layer.

In some embodiments herein, at least one of the first and second buffer layers may include one of a polymer and an elastomer each having a Young's modulus of 2 GPa or less.

In some embodiment, the semiconductor module may further comprise at least one passive device on at least one of the first and second surfaces.

In some embodiments herein, the module substrate may include a printed circuit board including at least one electrode to contact an external electronic device.

In some embodiments herein, the first semiconductor chip may include a first solder ball which is in contact with the top surface, and the second semiconductor chip may include a second solder ball which is in contact with the second surface.

The foregoing and/or other aspects and utilities of the present general inventive concept can also be achieved by providing a semiconductor module, including a module substrate having an upper surface and a lower surface, a conductive layer disposed on each of the upper and lower surfaces of the module substrate, and a buffer layer disposed on each of the upper and lower surfaces of the module substrate, each buffer layer being in contact with a respective one of the conductive layers to relieve stresses applied to the conductive layer.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1A is a top plan view illustrating an embodiment of a semiconductor module according to an embodiment of the present general inventive concept.

FIG. 1B is a cross-sectional view cut along a line I-I of FIG. 1A.

FIG. 1C is a cross-sectional view magnifying a portion of FIG. 1B.

FIG. 2A is a cross-sectional view illustrating a semiconductor module according to another embodiment of the present general inventive concept.

FIG. 2B is a cross-sectional view magnifying a portion of FIG. 2A.

FIG. 3A is a top plan view illustrating a semiconductor module according to another embodiment of the present general inventive concept.

FIG. 3B is a cross-sectional view cut along a line I-I of FIG. 3A.

FIG. 3C is a cross-sectional view magnifying a portion of FIG. 3B.

FIG. 4A is a cross-sectional view illustrating a semiconductor module according to yet another embodiment of the present general inventive concept.

FIG. 4B is a cross-sectional view magnifying a portion of FIG. 4A.

FIG. 5 is a perspective view illustrating an electronic apparatus comprising a semiconductor module according to another embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

In the drawings, the thickness of layers and regions are exaggerated for clarity. It will be understood that when an element such as a layer, region or substrate is referred to as being “on” another element, it can be directly on the other element, or intervening elements can also be present.

Furthermore, relative terms, such as “beneath”, can be used herein to describe one element's relationship to another elements as illustrated in the Figures. It will be understood that relative terms are intended to encompass different orientations of the device in addition to the orientation depicted in the Figures. For example, if the device in the Figures is turned over, elements described as “below” other elements would then be oriented “above” the other elements. The exemplary term “below”, can therefore, encompasses both an orientation of above and below.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second without departing from the teachings of the present invention. Like numbers refer to like elements throughout.

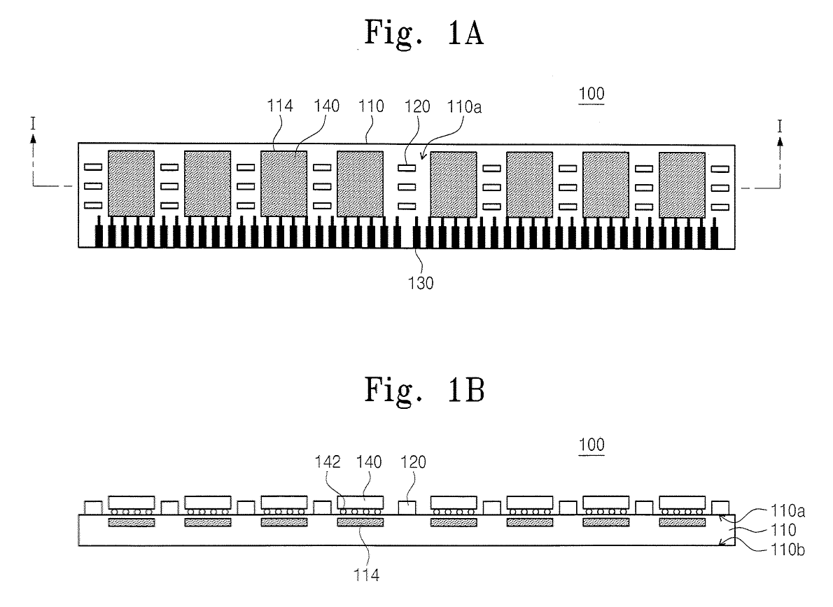

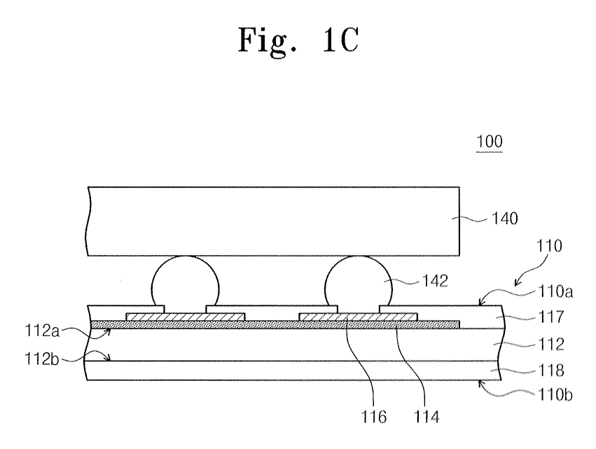

Referring to FIGS. 1A and 1B, a semiconductor module 100 according to an embodiment of the present general inventive concept may include a module substrate 110 having a top surface 110a on which a plurality of semiconductor chips 140 are mounted and a bottom surface 110b opposite the top surface 110a. Each of the semiconductor chips 140 may be electrically connected to the module substrate 110 by a plurality of solder balls 142. The plurality of semiconductor chips 140 may be disposed in a line on the top surface 110a of the module substrate 110. For example, the plurality of semiconductor chips 140 may be of the same kind, e.g., memory chips or logic chips. Alternatively, the plurality of semiconductor chips 140 may be of different kinds, e.g., mixed with memory chips and logic chips. The plurality of semiconductor chips 140 may be packaged in wafer level and then divided into respective ones by a sawing process.

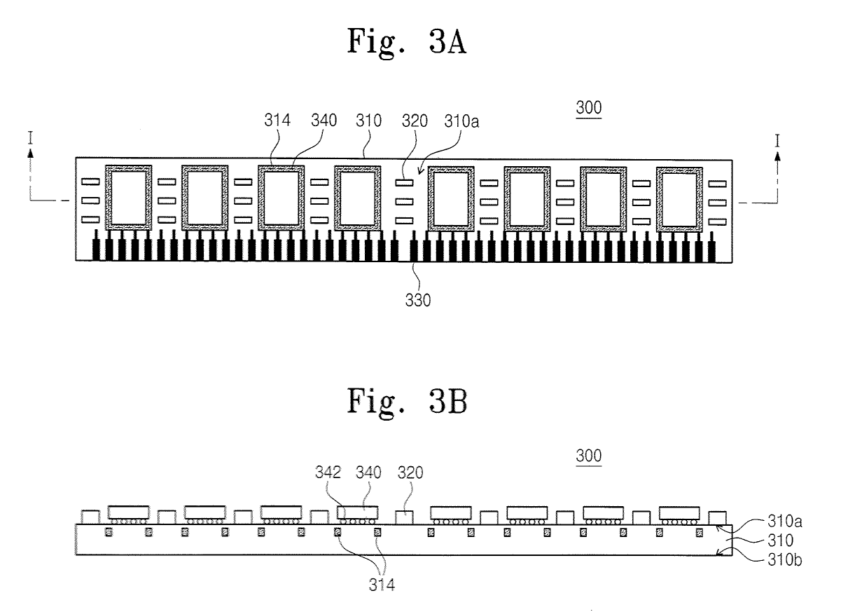

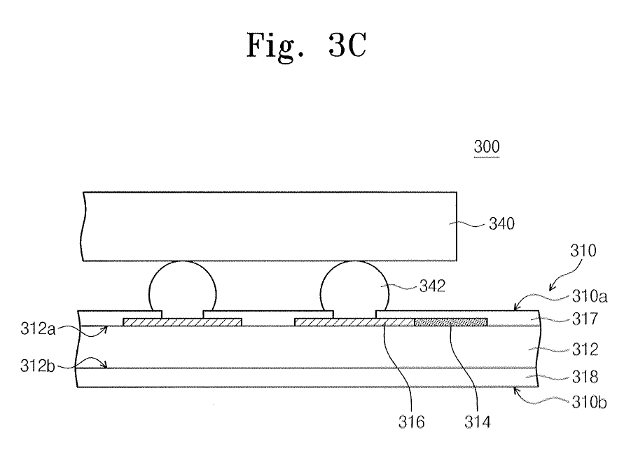

The module substrate 110 may be a printed circuit board on which at least one passive device 120 such as a register, a capacitor and an inductor, is disposed. The at least one passive device 120 may be disposed on the top surface 110a. The module substrate 110 may comprise a plurality of electrodes 130 electrically connected to an external electronic device, for example, a socket of a computer main-board. Further details of the module substrate 110 will be described later with reference to FIG. 3C.

The module substrate 110 may include a buffer layer 114. The buffer layer 114 may be disposed below the semiconductor chip 140. The buffer layer 114 may be a stress buffering layer to relieve stress, disturbing a stress concentration at a specific point. A size and/or area of the buffer layer 114 may be identical or similar to a size and/or area of the semiconductor chip 140. The buffer layer 114 may include material with a relatively low Young's modulus. For instance, the buffer layer 114 may be composed of a polymer or elastomer having a Young's modulus of 2 GPa or less.

Referring to FIG. 1C, the module substrate 110 may be so called a one layered structure in which the semiconductor chip 140 is mounted on one surface thereof. For instance, the module substrate 110 may have a core 112. The buffer layer 114 may be disposed on an upper surface 112a of the core 112, and a conductive layer 116 may be disposed on the buffer layer 114. The conductive layer 116 may be connected to the solder ball 142. An insulative layer 117 may be formed on the upper surface 112a to cover the buffer layer 114, and the insulative layer 117 may expose a portion of the conductive layer 116. A lower surface 112b, opposite the upper surface 112a of the core 112, may be covered with an insulative layer 118. The core 112 may be composed of Sn. The conductive layer 116 may be composed of Cu. The insulative layers 117 and 118 may be composed of prepreg (pre-impregnated composite fibers) or photo solder resist.

The solder ball 142 may suffer from a stress concentration due to the difference of a coefficient of thermal expansion (CTE) between the module substrate 110 and the semiconductor chip 140 during the thermal cycle (TC) and/or actual use. The buffer layer 114, however, can relieve the stress which is concentrated on the solder ball 142. Consequently, the buffer layer 114 can prevent the solder ball 142 from cracking and can also improve the solder joint reliability of the semiconductor module 100. Even with mechanical stress applied to the semiconductor module 100 due to different causes other than thermal causes as described above, the buffer layer 114 can relieve stresses that inhibit the solder ball 142 and the semiconductor module 100 from cracks and breakdown.

The module substrate 110 may be manufactured by the following method. The buffer layer 114 may be formed on the upper surface 112a of the core 112. The buffer layer 114 may be formed by screen printing, laminating, coating, dispensing, potting, or other well-known methods. A Cu film for the conductive layer 116 and prepreg for the insulative layer 117 may be formed successively on the upper surface 112a. The insulative layer 118 may be further formed on the lower surface 112b. The prepreg may be processed to form a circuit pattern. For instance, the circuit pattern may be formed by applying the light with some intensity to the prepreg for some time to polymerize a portion of the prepreg, e.g., the circuit pattern. A portion of Cu film, e.g., a portion that is not covered with the prepreg, may be etched to accomplish the module substrate 110.

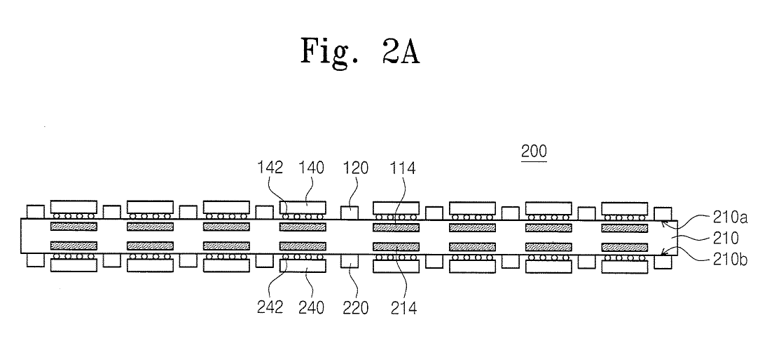

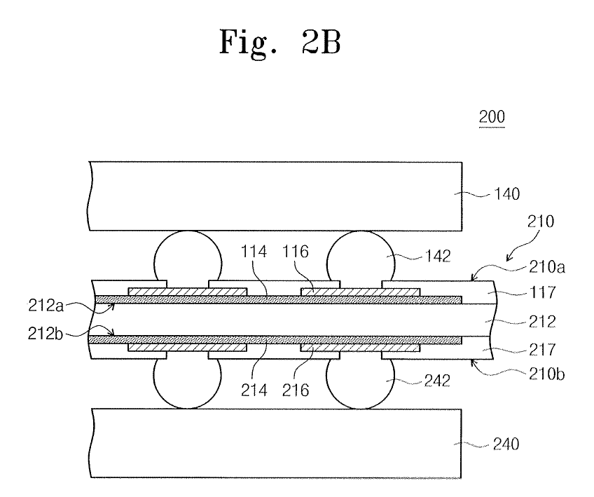

Referring to FIG. 2A, a semiconductor module 200 according to another embodiment of the present general inventive concept may comprise a module substrate 210 and the plurality of semiconductor chips 140 (referred to as first semiconductor chips hereinafter) mounted on a top surface 210a of the module substrate 210. The semiconductor module 200 may further comprise a plurality of second semiconductor chips 240 mounted on a bottom surface 210b opposite the top surface 210a. The semiconductor module 200 may comprise the plurality of passive devices 120 (referred to as first passive devices hereinafter) mounted on the top surface 210a and may further comprise a plurality of second passive devices 220 mounted on the bottom surface 210b. The buffer layer 114 (referred to as first buffer layer hereinafter) may be formed on the top surface 210a below the first semiconductor chip 140, and a second buffer layer 214 may be further formed on the bottom surface 210b below the second semiconductor chip 240.

A size and/or area of the second buffer layer 214 may be identical to or similar to a size and/or area of the second semiconductor chip 240. Similar to the first buffer layer 114, the second buffer layer 214 may comprise material with a relatively low Young's modulus. For instance, the second buffer layer 214 may be composed of a polymer or an elastomer having a Young's modulus of 2 GPa or less. The second buffer layer 214 may face the first buffer layer 114.

Referring to FIG. 2B, the module substrate 210 may be so called a two layered structure such that first and second semiconductor chips 140 and 240 are mounted on the top and bottom surfaces 210a and 210b, respectively. For instance, the module substrate 210 may have a core 212 with an upper surface 212a and a lower surface 212b opposite the upper surface 212a. The first buffer layer 114 and the insulative layer 117 (referred to as first insulative layer hereinafter) may be formed on the upper surface 212a. The conductive layer 116 (referred to as first conductive layer hereinafter) may be formed on the first buffer layer 114. Also, a second insulative layer 217 may be further formed on the lower surface 212b and a second conductive layer 216 may be further formed on the second buffer layer 214. The second conductive layer 216 may be electrically connected to a solder ball 242 attached to the second semiconductor chip 240. The second insulative layer 217 may expose a portion of the second conductive layer 216.

Referring to FIGS. 3A and 3B, a semiconductor module 300 according to another embodiment of the present general inventive concept may comprise a module substrate 310 with a top surface 310a on which a plurality of semiconductor chips 340 are mounted and a bottom surface 310b opposite the top surface 310a. The semiconductor module 300 may have a top plan view similar to the semiconductor module 100 depicted in FIG. 1A. The semiconductor chip 340 may be electrically connected to the module substrate 310 by a plurality of solder balls 342. A plurality of passive devices 320 may be disposed on the top surface 310a. The module substrate 310 may comprise a plurality of electrodes 330 for interconnection to an external device. The module substrate 310 may comprise a buffer layer 314 having a frame structure in the form of a band extending along the semiconductor chip 340. The buffer layer 314 may be a layer to buffer stress, and can be composed of a polymer or an elastomer having a Young's modulus of 2 GPa or less.

Referring to FIG. 3C, the module substrate 310 may be so called a one layered structure such that the semiconductor chip 340 is mounted on one surface thereof. For instance, the module substrate 310 may have a core 312 with an upper surface 312a on which a conductive layer 316 and the buffer layer 314 are formed, and a lower surface 312b opposite the upper surface 312a. The conductive layer 316 may be electrically connected to the solder ball 342. The buffer layer 314 may contact a lateral side of the conductive layer 316 to relieve stress applied to the solder ball 342, especially stress which is concentrated at an interface between the solder ball 342 and the conductive layer 316. This leads the semiconductor module 300 to improve solder joint reliability. An insulative layer 317 exposing a portion of the conductive layer 316 may be formed on the upper surface 312a. Another insulative layer 318 may be further formed on the lower surface 312b of the module substrate 310.

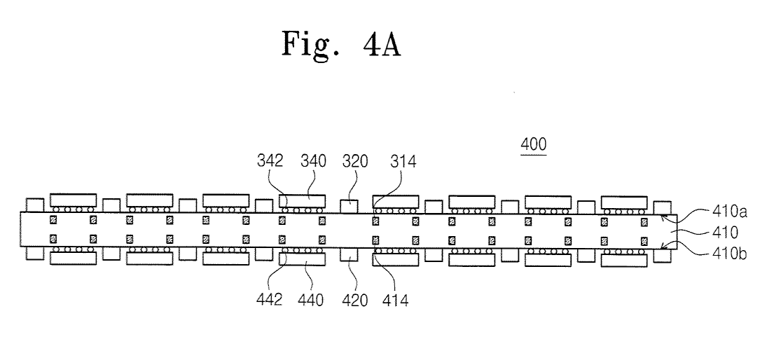

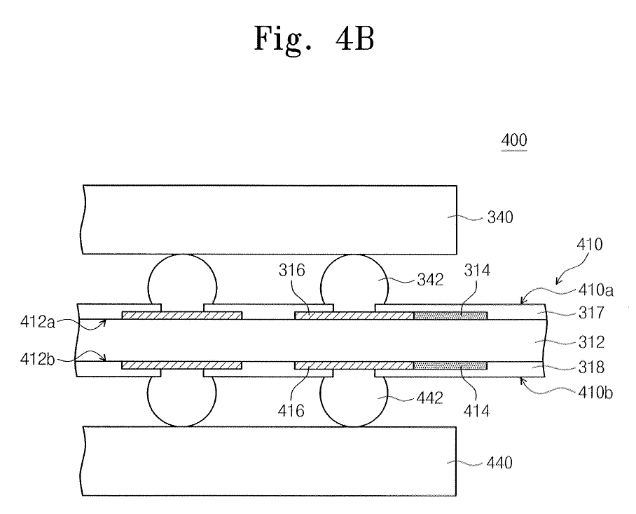

Referring to FIGS. 4A and 4B, a semiconductor module 400 according to yet another embodiment of the present general inventive concept may comprise a module substrate 410 and the plurality of semiconductor chips 340 (referred to as the first semiconductor chips hereinafter) mounted on a top surface 410a of the module substrate 410. The semiconductor module 400 may further comprise a plurality of second semiconductor chips 440 mounted on a bottom surface 410b opposite the top surface 410a. The semiconductor module 400 may comprise the plurality of passive devices 320 (referred to as first passive devices hereinafter) mounted on the top surface 410a and may further comprise a plurality of second passive devices 420 mounted on the bottom surface 410b. The buffer layer 314 (referred to as the first buffer layer hereinafter) may be formed on the top surface 410a below the first semiconductor chip 340 and a second buffer layer 414 may be further formed on the bottom surface 410b below the second semiconductor chip 440.

The second buffer layer 414 may have a frame structure in the form of a band extending along the second semiconductor chip 440. Similar to the first buffer layer 314, the second buffer layer 414 may comprise material with a relatively low Young's modulus, for example, polymer or elastomer having a Young's modulus of 2 GPa or less. The second buffer layer 414 may face the first buffer layer 314.

Referring to FIG. 4B, the module substrate 410 may be a so called two layered structure in which first and second semiconductor chips 340 and 440 are mounted on the top and bottom surfaces 410a and 410b, respectively. For instance, the module substrate 410 may have a core 312 with an upper surface 412a and a lower surface 412b opposite the upper surface 412a. The first buffer layer 314 and the insulative layer 317 (referred to as the first insulative layer hereinafter) may be formed on the upper surface 412a. The conductive layer 316 (referred to as the first conductive layer hereinafter) may be formed to be laterally in contact with the first buffer layer 314 on the top surface 310a. Also, the second buffer layer 414 and a second insulative layer 417 may be further formed on the lower surface 412b and a second conductive layer 416 may be further formed to be laterally in contact with the second buffer layer 414 on the lower surface 412b. The second conductive layer 416 may be electrically connected to a solder ball 442 attached to the second semiconductor chip 440. The second insulative layer 417 may expose a portion of the second conductive layer 416.

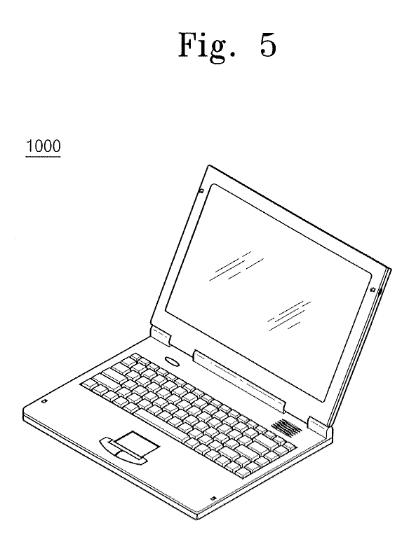

Referring to FIG. 5, at least one of semiconductor modules 100 through 400 described above may be applied to an electronic apparatus, such as a laptop computer 1000. The electronic apparatus is not limited to being an laptop computer 1000. For example, the electronic apparatus may comprise a desktop computer, a camcorder, a mobile phone, a game player, a portable multimedia players, an MP3 player, a display apparatus such LCD and PDP, a memory card and the like. Especially, the laptop computer 1000 may be used without malfunctions and/or errors even under severe thermal environments.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor module comprising:
a first semiconductor chip; and
a module substrate having a top surface on which the first semiconductor chip is mounted and a second surface opposite the top surface, the module substrate comprising a first buffer layer to relieve stress occurring due to a difference of thermal expansions between the first semiconductor chip and the module substrate.

2. The semiconductor module of claim 1, wherein the first buffer layer is located inside the module substrate, and a size and area thereof are identical to those of the first semiconductor chip.

3. The semiconductor module of claim 2, wherein the module substrate further comprises:
a core having a third surface and a fourth surface opposite the third surface;
a first conductive layer disposed on the third surface and electrically connected to the first semiconductor chip; and
a first insulative layer exposing a portion of the first conductive layer, wherein the first buffer layer is interposed between the third surface and the first conductive layer.

4. The semiconductor module of claim 1, wherein the first buffer layer is located inside the module substrate and comprises a frame structure in the form of a band extending along the first semiconductor chip.

5. The semiconductor module of claim 4, wherein the module substrate further comprises:
a core having a third surface and a fourth surface opposite the third surface;
a first conductive layer disposed on the third surface and electrically connected to the first semiconductor chip; and
a first insulative layer exposing a portion of the first conductive layer,
wherein the first buffer layer lies on the third surface to contact a lateral side of the first conductive layer.

6. The semiconductor module of claim 1, wherein the first buffer layer comprises one of a polymer and an elastomer each having a Young's modulus of 2 GPa or less.

7. The semiconductor module of claim 1, wherein the module substrate further comprises:
a second semiconductor chip mounted on the second surface; and
a second buffer layer to relieve stress occurring due to a difference of thermal expansions between the second semiconductor chip and the module substrate.

8. The semiconductor module of claim 7, wherein the module substrate further comprises:
a core having a third surface and a fourth surface opposite the third surface;
a first conductive layer disposed on the third surface and electrically connected to the first semiconductor chip;
a first insulative layer exposing a portion of the first conductive layer;
a second conductive layer disposed on the fourth surface and electrically connected to the second semiconductor chip; and
a second insulative layer exposing a portion of the second conductive layer,
wherein the first buffer layer is interposed between the third surface and the first conductive layer, and the second buffer layer is interposed between the fourth surface and the second conductive layer.

9. The semiconductor module of claim 7, wherein the second buffer layer is located inside the module substrate and comprises a frame structure in the form of band extending along the second semiconductor chip.

10. The semiconductor module of claim 9, wherein the module substrate further comprises:
a core having a third surface and a fourth surface opposite the third surface;
a first conductive layer disposed on the third surface and electrically connected to the first semiconductor chip;
a first insulative layer exposing a portion of the first conductive layer;
a second conductive layer disposed on the fourth surface and electrically connected to the second semiconductor chip; and
a second insulative layer exposing a portion of the second conductive layer,
wherein the first buffer layer lies on the third surface to contact a lateral side of the first conductive layer, and the second buffer layer lies on the fourth surface to contact a later side of the second conductive layer.

11. The semiconductor module of claim 7, wherein at least one of the first and second buffer layers comprises one of polymer and elastomer each having Young's modulus of 2 GPa or less.

12. The semiconductor module of claim 7, further comprising at least one passive device on at least one of the first and second surfaces.

13. The semiconductor module of claim 7, wherein the module substrate comprises a printed circuit board including at least one electrode for contacting an external electronic device.

14. The semiconductor module of claim 7, wherein the first semiconductor chip comprises a first solder ball which is contacted with the top surface, and the second semiconductor chip comprises a second solder ball which is contacted with the second surface.

15. A semiconductor module, comprising:
a module substrate having an upper surface and a lower surface;
a conductive layer disposed on each of the upper and lower surfaces of the module substrate; and
a buffer layer disposed on each of the upper and lower surfaces of the module substrate, each buffer layer being in contact with a respective one of the conductive layers to relieve stresses applied to the conductive layer.

16. The semiconductor module of claim 15, wherein the buffer layer is composed of a polymer or an elastomer having a Young's modulus of 2 GPa or less.

17. The semiconductor module of claim 15, wherein the buffer layer contacts a lateral side of the respective conductive layer.

18. The semiconductor module of claim 15, wherein the buffer layer is disposed between the module substrate and the respective conductive layer.

19. The semiconductor module of claim 15, wherein a stress applied to the conductive layer includes solder balls being electrically connected thereto.
